(19) United States
(12) Patent Application Publication
(10) Pub. No.: US 2017/0153372 A1
(43) Pub. Date: Jun. 1, 2017

(54) WIRE GRID POLARIZER PLATE AND METHOD FOR MANUFACTURING THE SAME

(71) Applicant: Samsung Display Co. Ltd., Yongin-si (KR)

(72) Inventors: Su Kyoung YANG, Yongin-si (KR); Moon Jung AN, Hwaseong-si (KR); Chan Woo YANG, Siheung-si (KR); Dong Min LEE, Anyang-si (KR); Ju Hyun LEE, Seongnam-si (KR); Gug Rae JO, Asan-si (KR)

(21) Appl. No.: 15/184,255

(22) Filed: Jun. 16, 2016

(30) Foreign Application Priority Data
Nov. 27, 2015 (KR) 10-2015-0167412

(51) Int. Cl. G02B 5/30; C23C 14/08; C23C 14/34; C23C 14/04

(52) U.S. Cl. CPC G02B 5/3058; C23C 14/042; C23C 14/081; C23C 14/083; C23C 14/085; C23C 14/087; C23C 14/08; C23C 14/3457

(57) ABSTRACT

A wire grid polarizer plate includes a transparent substrate, metal partition walls and metal oxide partition walls. The metal partition walls are disposed on the transparent substrate and spaced apart from one another. The metal partition walls includes at least one metal selected from aluminum (Al), titan (Ti), molybdenum (Mo), chrome (Cr), silver (Ag), copper (Cu), nickel (Ni) and cobalt (Co). The metal oxide partition walls are disposed on the metal partition walls. The metal oxide partition walls includes an oxide of the at least one metal. An average of surface roughness of the wire grid polarizer plate is about 4 nm or less when a thickness of the metal oxide partition walls is equal to about 300 Å.

This application claims priority to Korean Patent Application No. 10-2015-0167412 filed on Nov. 27, 2015, and all the benefits accruing therefrom under 35 U.S.C. 119, the content of which in its entirety is herein incorporated by reference.

### BACKGROUND

1. Field

The disclosure relates to a wire grid polarizer plate and a method for manufacturing the wire grid polarizer.

2. Description of the Related Art

Generally, a wire grid pattern refers to an array of parallel conductor lines to polarize light incident thereto.

A wire grid pattern having a period or pitch smaller than the wavelength of a light has polarization characteristics. In such a wire grid pattern, a component of an unpolarized incident light in the wire direction is reflected, while a component of the unpolarized incident light perpendicular to the wire direction is transmitted such that the reflected component may be reused.

### SUMMARY

Embodiments of the disclosure provide a wire grid polarizer plate in which wire grid pattern defects due to surface unevenness of a metal layer are reduced.

Embodiments of the disclosure also provide a method of manufacturing a wire grid polarizer plate with improved processing efficiency.

According to an exemplary embodiment, a wire grid polarizer plate includes a transparent substrate, metal partition walls and metal oxide partition walls. The metal partition walls are disposed on the transparent substrate and spaced apart from one another. The metal partition walls includes at least one metal selected from aluminum (Al), titan (Ti), molybdenum (Mo), chrome (Cr), silver (Ag), copper (Cu), nickel (Ni) and cobalt (Co). The metal oxide partition walls are disposed on the metal partition walls. The metal oxide partition walls are made of an oxide of the at least one metal. An average of surface roughness of the wire grid polarizer plate is about 4 nanometers (nm) or less when a thickness of the metal oxide partition walls is equal to about 300 angstrom (Å).

According to another exemplary embodiment, a method of manufacturing a wire grid polarizer plate includes performing continuous sputtering depositions. The performing the continuous sputtering depositions includes injecting an inert gas into a sputter chamber to deposit a metal layer on a transparent substrate by sputtering and then injecting the inert gas along with an oxygen gas into the sputter chamber to deposit a metal oxide layer on the metal layer by sputtering. The method further includes providing resin partition walls on the metal oxide layer, patterning the metal oxide layer using the resin partition walls as a mask to form metal oxide partition walls on the metal layer and patterning the metal layer using the metal oxide partition walls as a mask to form the metal partition walls on the transparent substrate. The metal layer includes at least one metal selected from aluminum (Al), titan (Ti), molybdenum (Mo), chrome (Cr), silver (Ag), copper (Cu), nickel (Ni) and cobalt (Co), and the metal oxide layer includes an oxide of the at least one metal.

According to another exemplary embodiment, a method of manufacturing a wire grid polarizer plate includes injecting an inert gas into a sputter chamber to deposit a metal layer on a transparent substrate by sputtering, providing resin partition walls on the metal layer, injecting the inert gas along with an oxygen gas into the sputter chamber to deposit a metal oxide layer on the resin partition walls and the metal layer by sputtering, stripping the resin partition walls to form metal oxide partition walls on the metal layer, and patterning the metal layer using the metal oxide partition walls as a mask to form the metal partition walls on the transparent substrate. The metal layer includes at least one metal selected from aluminum (Al), titan (Ti), molybdenum (Mo), chrome (Cr), silver (Ag), copper (Cu), nickel (Ni) and cobalt (Co). The metal oxide layer includes an oxide of the at least one metal.

According to exemplary embodiments, hillock protruding from a metal layer of a wire grid polarizer plate may be effectively prevented from being formed, and thus surface unevenness may be reduced.

According to exemplary embodiments, all of processes of methods of manufacturing a wire grid polarizing plate are carried out in a single sputter chamber, so that processing efficiency and productivity of the wire grid polarizer plate can be improved.

### BRIEF DESCRIPTION OF THE DRAWINGS

The above and other features of the disclosure will become more apparent by describing in detail exemplary embodiments thereof with reference to the attached drawings, in which:

FIGS. 1 to 6 are perspective views schematically illustrating a method of manufacturing a wire grid polarizing plate according to an exemplary embodiment of the invention;

FIG. 7 is an enlarged view of portion A of FIG. 6;

FIG. 8 is a graph showing voltage and electric current of the sputter chamber versus flow rate of oxygen supplied into the sputter chamber;

FIGS. 9 to 14 are perspective views schematically illustrating a method of manufacturing a wire grid polarizing plate according to an alternative exemplary embodiment of the invention;

FIG. 15 is an enlarged view of area A′ of FIG. 14;

FIG. 16 is a view schematically showing an existing method of manufacturing a wire grid polarizing plate;

FIG. 17 is an image showing a pattern defect on the wire grid polarizing plate caused by hill lock.

FIG. 18 is a graph showing results obtained by comparing and analyzing the RMS of the surface roughness of an exemplary embodiment of the wire grid polarizing plate according to the invention with that of the wire grid polarizing plate according to Comparative Example 1;

FIG. 19 is a graph showing results obtained by comparing and analyzing the Rp−v of the surface roughness of an exemplary embodiment of the wire grid polarizing plate according to the invention with that of the wire grid polarizing plate according to Comparative Example 1;

FIG. 20 is an image showing the surface of the wire grid polarizing plate according to Comparative Example 1;

FIG. 21 is an image showing the surface of an exemplary embodiment of the wire grid polarizing plate according to the invention;

FIG. 22 is a graph for comparing degree of polarization of an exemplary embodiment of the wire grid polarizing plate according to the invention with that of the wire grid polarizing plate according to Comparative Example 1;

FIG. 23 is a graph for comparing transmissivity of an exemplary embodiment of the wire grid polarizing plate according to the invention with that of the wire grid polarizing plate according to Comparative Example 1;

FIG. 24 is a graph showing relationship between the thickness of aluminum oxide partitioning walls (angstrom (Å)) and residual film ratio (%) after the aluminum oxide (AlOₓ) layer has been patterned using resin partitioning walls as a mask;

FIG. 25 is a graph showing relationship between the thickness of aluminum oxide partitioning walls (Å) and residual film ratio of aluminum oxide partitioning walls (%) after the aluminum layer has been patterned using aluminum oxide (AlOₓ) partitioning walls as a mask;

FIG. 26 is a graph showing the relationship among the residual film ratio (%) of resin partitioning walls, residual film ratio (%) of aluminum oxide partitioning walls and the thickness (Å) of aluminum oxide partitioning walls, when the etch selectivity between the resin partitioning walls and the aluminum oxide partitioning walls is 1:0.8; and

FIG. 27 is a graph showing the relationship among the residual film ratio (%) of resin partitioning walls, residual film ratio (%) of silicon oxide partitioning walls and the thickness (Å) of silicon oxide partitioning walls, when the etch selectivity between the resin partitioning walls and the silicon oxide (SiOₓ) partitioning walls is 1:1.5.

### DETAILED DESCRIPTION

Features of the invention and methods of accomplishing the same may be understood more readily by referencing the following detailed description of preferred embodiments and the accompanying drawings. The invention may, however, be embodied in many different forms and are not limited to the embodiments set forth herein. Rather, these embodiments are provided to help illustrate the invention to those of ordinary skill in the art.

In the drawings, the thickness of layers and regions are exaggerated for clarity. It will be understood that when an element or layer is referred to as being “on”, “connected to” or “coupled to” another element or layer, the element or layer may be directly on, connected or coupled to another element or layer, or intervening elements or layers. In contrast, when an element is referred to as being “directly on”, “directly connected to” or “directly coupled to” another element or layer, there are no intervening elements or layers present. As used herein, connected may refer to elements being physically, electrically and/or fluidly connected to each other.

Like numbers refer to like elements throughout. “Or” means “and/or.” As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections are not limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially related terms, such as “below”, “lower”, “under”, “above”, “upper” and the like, may be used herein for ease of description to describe the relationship of one element or feature to another element(s) or feature(s) as illustrated in the figures. It will be understood that the spatially related terms are intended to encompass different orientations of the device in use or operation, in addition to the orientation depicted in the figures. For example, if the device in the figures is turned over, elements described as “below” or “beneath” relative to other elements or features would then be oriented “above” relative to the other elements or features. Thus, the exemplary term “below” can encompass both an orientation of above and below. The device may be otherwise oriented (rotated 90 degrees or at other orientations) and the spatially related descriptors used herein may be interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises”, “comprising”, “includes” and/or “including”, when used in this specification, specify the presence of stated features, integers, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the invention, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. In an exemplary embodiment, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, exemplary embodiments of the disclosure will be described in detail with reference to the accompanying drawings.

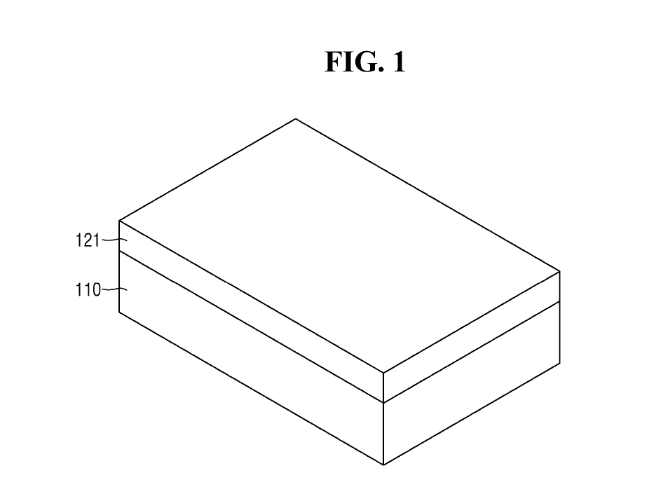

FIGS. 1 to 6 are perspective views schematically illustrating a method of manufacturing a wire grid polarizer plate 100 according to an exemplary embodiment of the invention.

FIG. 1 schematically illustrates a process of forming a metal layer 121 on a transparent substrate 110 by sputtering.

In one exemplary embodiment, for example, the metal layer 121 may be formed in such a manner that the transparent substrate 110 is disposed at an anode in a sputter chamber while a sputtering target material is disposed at an cathode in the sputter chamber, an inert gas is injected into the sputter chamber, a plasma is generated by applying voltage to the anode and the cathode in a vacuum state, and atoms or ions ejected from the sputtering target material are deposited on the transparent substrate 110. The inert gas may be argon (Ar) gas, for example.

The material of the transparent substrate 110 may be selected as appropriate for its use or processes as long as it transmits visible lay. In one exemplary embodiment, for example, the transparent substrate 110 may include or be made of, but is not limited to, at least one material selected from a variety of polymer compounds including glass, quartz, acryl, triacetylcellulose (“TAC”), cyclic olefin copolymer (“COP”), cyclic olefin polymer (“COC”), polycarbonate (“PC”), polyethylene naphthalate (“PET”), polyimide (“PI”), polyethylene naphthalate (“PEN”), polyether sulfone (“PES”), polyarylate (“PAR”), etc. The transparent substrate 110 may include or be made of an optical film material having a certain degree of flexibility.

The sputtering target material may be a metal having a high reflectivity. In one exemplary embodiment, for example, the sputtering target material may include or be made of at least one metal selected from aluminum (Al), titanium (Ti), molybdenum (Mo), chrome (Cr), silver (Ag), copper (Cu), nickel (Ni) and cobalt (Co). In such an embodiment, the sputtering target material may include or be made of at least one of aluminum (Al), titanium (Ti), molybdenum (Mo), chrome (Cr), silver (Ag), copper (Cu), nickel (Ni) and cobalt (Co) or an alloy thereof. In an exemplary embodiment, the sputtering target material may be aluminum.

The metal layer 121 may be made of at least one of aluminum (Al), titanium (Ti), molybdenum (Mo), chrome (Cr), silver (Ag), copper (Cu), nickel (Ni) and cobalt (Co) or an alloy thereof. The thickness of the metal layer 121 may be adjusted depending on a deposition time, and may be about 1,500 angstrom (Å) or more, for example.

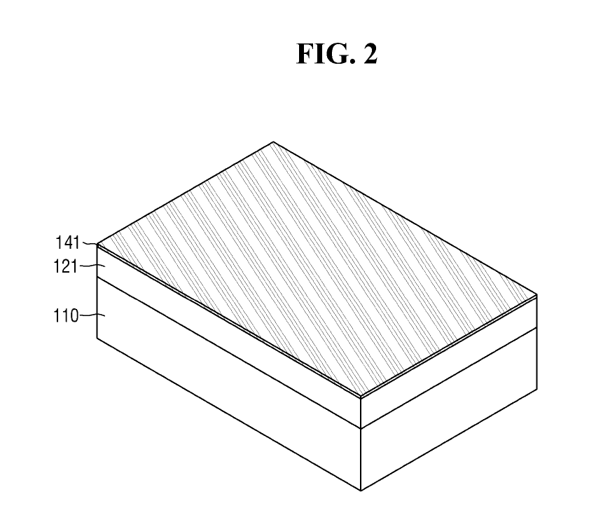

FIG. 2 schematically illustrates a process of forming a metal oxide layer 141 on the metal layer 121 by sputtering. The process of forming the metal oxide layer 141 may be carried out in the sputter chamber continuously after the metal layer 121 is formed.

In one exemplary embodiment, for example, after the metal layer 121 is formed on the transparent substrate 110, an inert gas and oxygen gas are injected into the sputter chamber, voltage is applied to the anode and cathode in a vacuum state to generate a plasma, and atoms or ions ejected from the sputtering target material and oxygen ions are deposited on the transparent substrate 100, thereby forming the metal oxide layer 141.

In one exemplary embodiment, for example, the metal oxide layer 141 may include or be made of at least one of aluminum (Al), titanium (Ti), molybdenum (Mo), chrome (Cr), silver (Ag), copper (Cu), nickel (Ni) and cobalt (Co) or an alloy thereof. In an exemplary embodiment, where the sputtering target material is aluminum, the metal layer may be an aluminum layer and the metal oxide layer may be an aluminum oxide layer.

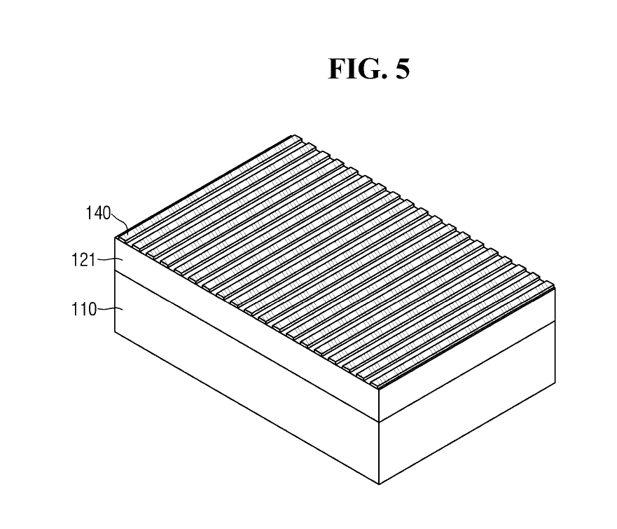

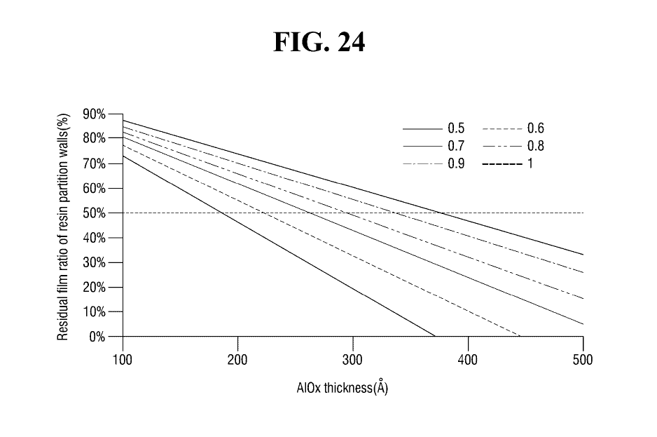

The thickness of the metal oxide layer 141 may be adjusted depending on a deposition time. In one exemplary embodiment, for example, the thickness of the metal oxide layer 141 may be in a range from about 100 Å to about 1,500 Å by adjusting the deposition time. The metal oxide layer 141 may be patterned to form metal oxide partition walls 140 (see FIG. 5), which may works as a mask for patterning the metal layer 121. Accordingly, to achieve residual film ratio substantially equal to that achieved by silicon oxide (SiOₓ) partition walls used as a mask for forming an existing wire grid pattern, the thickness of the metal oxide layer 141 may be approximately 300 angstrom (Å) or more (see FIGS. 24 to 27).

The metal oxide layer 141 has electric conductivity and light reflectivity. Such metallic characteristics may be adjusted depending on the flow rate of the oxygen gas supplied into the sputter chamber.

The inventors of the application has found out that the metal oxide layer 141 may have metallic characteristics when the power supplied to the sputter chamber is equal to about 3 kilowatts (kW), the flow rate of argon (Ar) introduced into the sputter chamber is equal to about 30 standard cubic centimeters per minute (sccm), and the flow rate of the oxygen gas is equal to about 30 sccm or less.

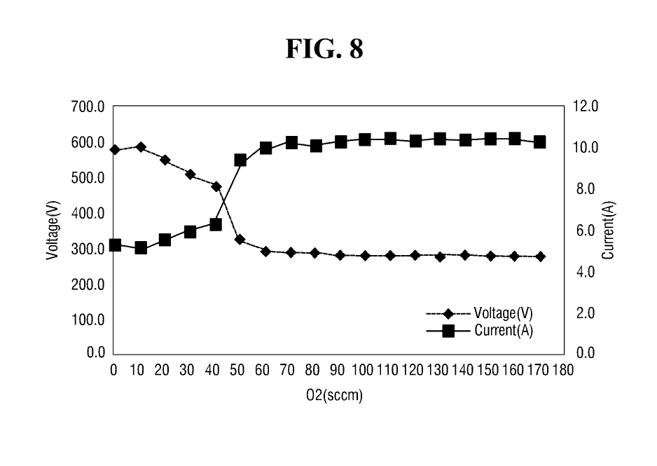

FIG. 8 is a graph showing voltage and electric current of the sputter chamber versus flow rate of oxygen supplied into the sputter chamber. FIG. 8 shows results of measuring voltage and electric current of the sputter chamber while varying flow rate of oxygen supplied into the sputter chamber, with the power supplied to the sputter chamber fixed to about 3 kW, the flow rate of argon (Ar) supplied into the sputter chamber fixed to about 30 sccm.

Referring to FIGS. 2 and 8, when the flow rate of the oxygen gas is approximately 50 sccm or less, the metal oxide layer 141 lost its metallic characteristics and became a transparent insulator. In other words, when the voltage of the sputter chamber is about 300 volts (V) or less, the metal oxide layer 141 lost its metallic characteristics and became a transparent insulator, such that the metal oxide partition walls 140 (see FIG. 5) formed by patterning the metal oxide layer 141 may not effectively function as a mask for patterning the metal layer 121.

When the flow rate of the oxygen gas is approximately about 50 sccm or less, the metal oxide layer 141 exhibited metallic characteristics, and the metal oxide partition walls 140 (see FIG. 5) formed by pattering the metal oxide layer 141 may be effectively used as a mask for patterning the metal layer 121.

The inventors of the application has confirmed that the metal oxide layer 141 exhibited better metallic characteristics when the voltage of the sputter chamber is about 500 V or higher, i.e., the flow rate of the oxygen gas is approximately between about 30 sccm and about 40 sccm. In addition, the metal oxide partition walls 140 (see FIG. 5) exhibited a desirable hardness to be used as a mask for patterning the metal layer 121.

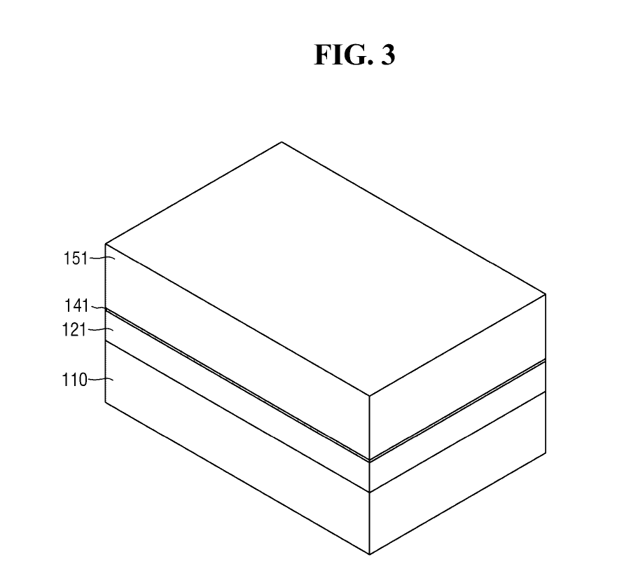

FIG. 3 schematically illustrates a process of forming a resin layer 151 on the metal oxide layer 141. The resin layer 151 may be a photoresist layer or a polymer material layer including a thermoplastic polymer. The material of the resin layer 151 may be selected appropriately depending on a patterning method such as a photolithography, imprint lithography, etc.

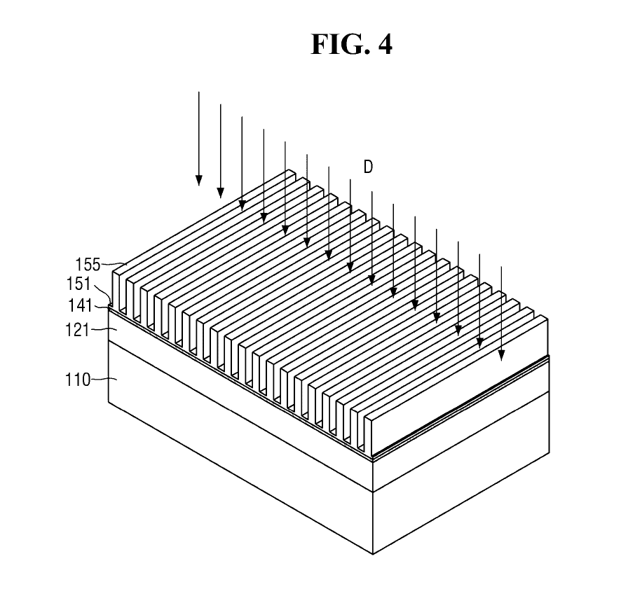

FIG. 4 shows a process of patterning the metal oxide layer 141 in such a manner that the resin layer 151 is patterned using a nano imprint mold (not shown) to form resin partition walls 155 and then an etching gas D is introduced from above the resin partition walls 155 to strip residual resin layer 151 and some portions of the metal oxide layer 141 which is not covered by the resin partition walls 155. The etching gas D may be chlorine (Cl) gas, for example.

The resin partition walls 155 may function as a mask for patterning the metal oxide layer 141. In one exemplary embodiment, for example, the resin partition walls 155 may be disposed spaced apart from one another with a distance of approximately about 100 nanometers (nm) or less.

FIG. 5 shows the metal oxide layer 141 shown in FIG. 4 after patterning. Referring to FIG. 5, the metal oxide partition walls 140 are formed by patterning the method oxide layer 141. The metal oxide partition walls 140 are provided on the metal layer 121 spaced apart from one another. The metal oxide partition walls 140 may function as a mask for patterning the metal layer 121. The etch selectivity between the resin partition walls 155 and the metal oxide partition walls 140 may be in a range from about 1:0.8 to about 1:1. The thickness of the metal oxide partition walls 140 may be in a range about 300 Å to about 400 Å0 (see FIGS. 24 to 27).

The metal oxide partition walls 140 may be disposed spaced apart from one another with a distance of approximately 100 nm or less and may have a line width of approximately 100 nm or less.

In one exemplary embodiment, for example, where the metal layer 121 is an aluminum layer and the metal oxide partition walls 140 are aluminum oxide partition walls, chlorine gas may be used as an etching gas (not shown) for patterning the metal layer 121. Since aluminum oxide is etched very little by the chlorine gas, there is difference in chemically etched amount between the metal layer 121 and the metal oxide partition walls 140, so that the metal oxide partition walls 140 may effectively function as a mask for patterning the metal layer 121.

In addition, since the Mohs hardness of the metal oxide partition walls 140 is larger than that of the metal layer 121, there is difference in etched amount by mechanical reaction between the metal layer 121 and the metal oxide partition walls 140, and, therefore, the metal oxide partition walls 140 may effectively function as a mask for patterning the metal layer 121.

In one exemplary embodiment, for example, where the metal layer 121 is an aluminum layer and the metal oxide partition walls 140 are aluminum oxide partition walls, the Mohs hardness of aluminum is about 2.75 while that of aluminum oxide is about 9 or higher, and, therefore, the metal oxide partition walls 140 may effectively function as a mask for patterning the metal layer 121.

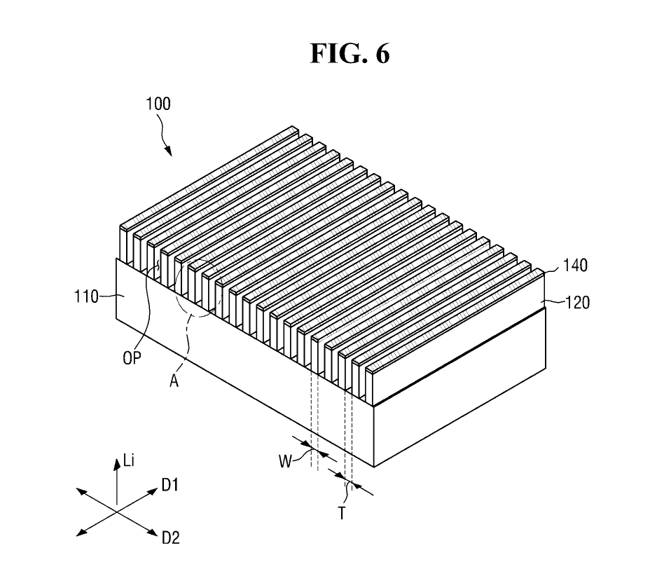

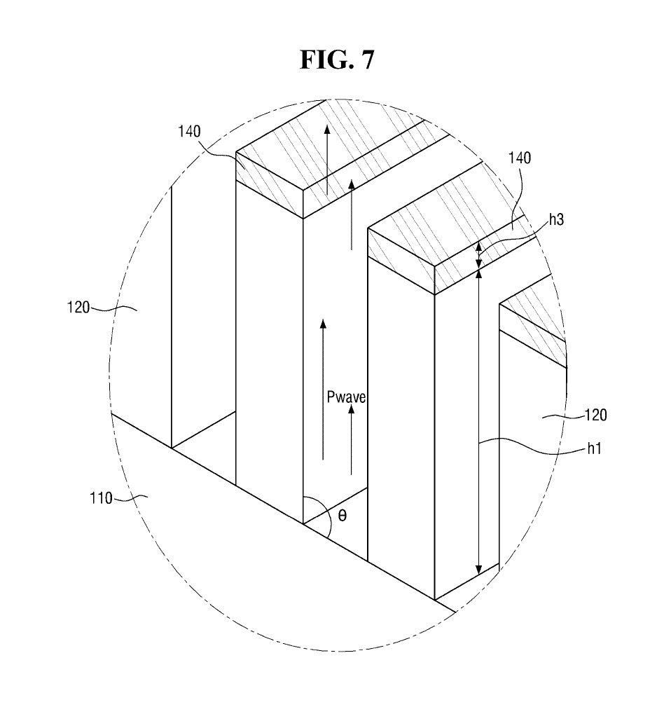

FIG. 6 shows an exemplary embodiment of the wire grid polarizer plate 100 formed by patterning the metal layer 121 using the metal oxide partition walls 140 as a mask. FIG. 7 is an enlarged view of portion A of FIG. 6.

Referring to FIGS. 6 and 7, the metal partition walls 120 are disposed on the transparent substrate 110 spaced apart from one another, and the metal oxide partition walls 140 are disposed on the metal partition walls 120. The metal partition walls 120 are extended in a first direction D1 and disposed spaced apart from one another by a predetermined gap in a second direction D2 perpendicular to the first direction D1.

Light Li incident on the wire grid polarizer plate 100 is polarized by the metal partition walls 120. The metal partition walls 120 spaced apart from one another by a predetermined gap transmit a first polarized light of the incident light Li while reflects a second polarized light perpendicular to the first polarized light. When the light Li is incident on the wire grid polarizer plate 100, S-wave of the incident light Li that is a polarization component parallel to the direction in which the metal partition walls 120 extends, (e.g., a polarization component in the first direction D1) are reflected by the metal partition walls 120, and P-wave that is a polarization component parallel to a direction perpendicular to the direction in which the metal partition walls 120 extends (e.g., a polarization component in the second direction D2) is transmitted through the metal partition walls 120 as an effective refractive medium thereof

The metal partition walls 120 may have, but is not limited to, a line width W of approximately 100 nm or less, a thickness h1 of approximately 150 nm or more, and a gap T of approximately 100 nm.

The metal oxide partition walls 140 may have, but is not limited to, a line width W of approximately 100 nm or less, a thickness h3 of approximately 30 nm or more, and a gap T of approximately 100 nm.

The metal oxide partition walls 140 may be formed in a way such that the metal partition walls 120 protrude upwardly in a direction substantially perpendicular to the transparent substrate 110. Accordingly, the metal partition walls 120 have a vertical etch profile.

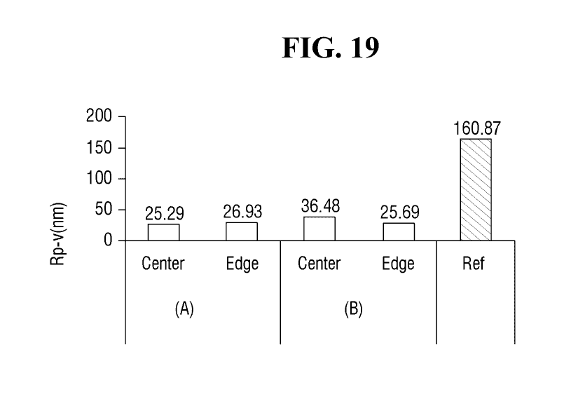

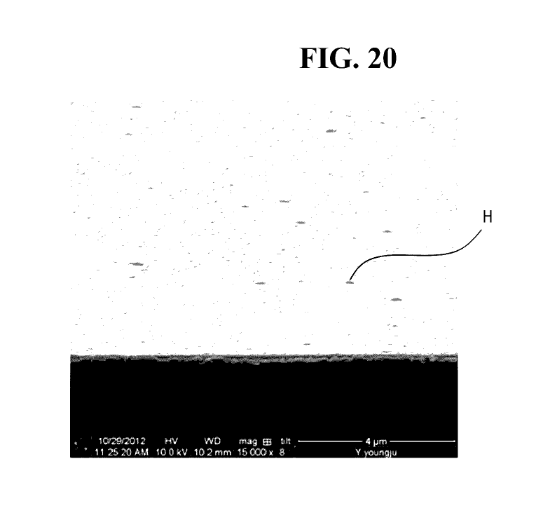

The angle θ formed by the metal partition walls 120 and the transparent substrate 110 when viewed from a side view may be in a range from about 88° to about 90°. The degree of polarization of the wire grid polarizer plate 100 is improved as the angle θ becomes larger, i.e., the metal partition walls 120 get closer to the right angle with respect to the transparent substrate 110. The wire grid polarizer plate 100 may have the metal partition walls 120 formed substantially vertical to the transparent substrate 110 and thus may have a degree of polarization of 99.9960% or higher. The wire grid polarizer plate 100 may have an average of surface roughness of about 4 nm or less when the thickness h3 of the metal oxide partition walls 140 is equal to about 30 nm. In an exemplary embodiment of the wire grid polarizer plate 100, the average of differences Rp−v between the peak in cross section Rp and valley in cross section Rv of the metal oxide partition walls 104 is equal to about 50 nm or less (see Tables 1 to 3 and FIGS. 19 and 20).

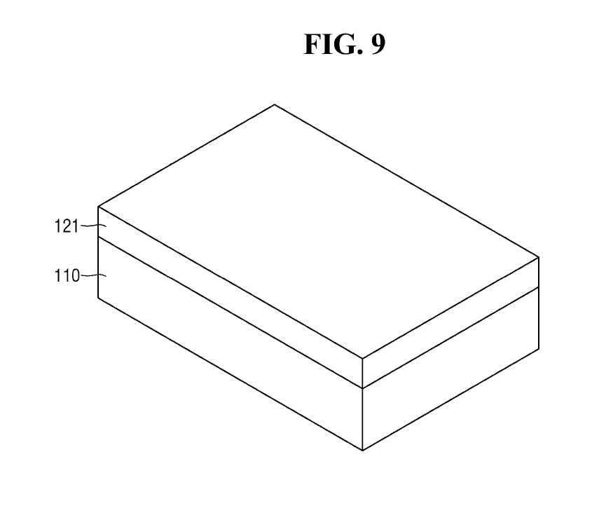

FIGS. 9 to 14 are perspective views schematically illustrating a method of manufacturing a wire grid polarizer plate 100 according to an alternative exemplary embodiment of the invention. The method of manufacturing the wire grid polarizer plate 100 shown in FIGS. 9 to 14 are different from the method of manufacturing a wire grid polarizer plate shown in FIGS. 1 to 6 in that the former does not include the continuous sputtering deposition.

In an exemplary embodiment, the method of manufacturing a wire grid polarizer plate 100 includes forming a metal layer 121 on a transparent substrate 110 and then forming a resin layer 151 on the metal layer 121. In such an embodiment, the method further includes patterning the resin layer 151 to form resin partition walls 155, and depositing a metal oxide layer 141 on the resin partition walls 155, and some portions of the metal layer 121 between the resin partition walls 155 are exposed through the resin partition walls 155.

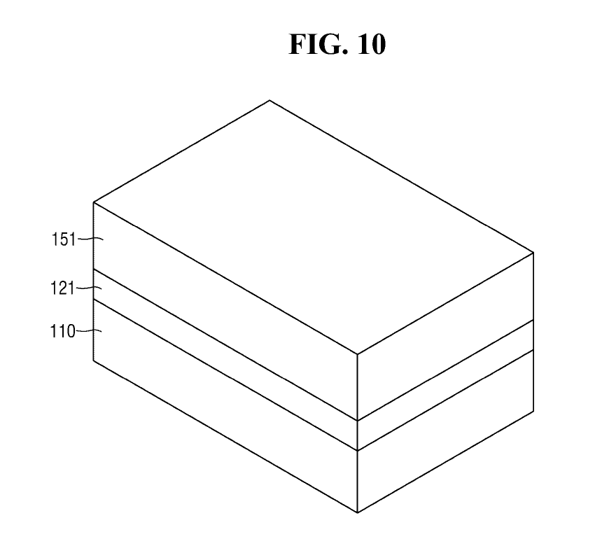

FIGS. 9 and 10 schematically illustrate a process of forming the metal layer 121 on the transparent substrate 110 by sputtering, and a process of forming the resin layer 151 on the metal layer 121, respectively.

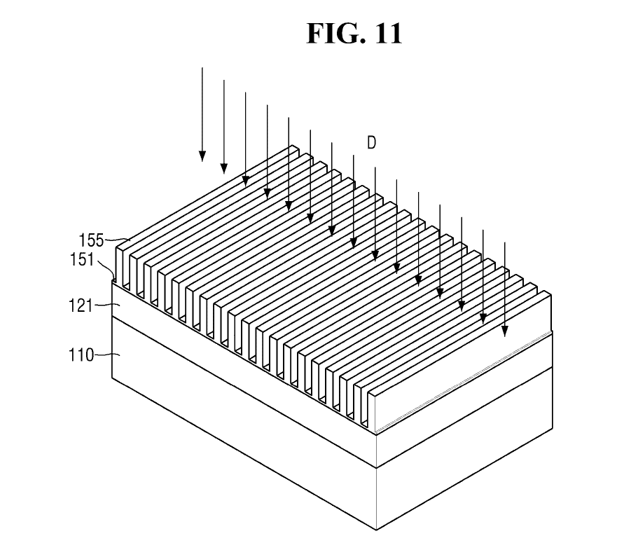

FIG. 11 schematically illustrates a process of patterning the resin layer 151 using a nano imprint mold (not shown) to form the resin partition walls 155 and then introducing an etching gas D from above the resin partition walls 155 to strip residual resin layer 151. By stripping the residual resin layer 151, some portions of the metal layer 121 between the resin partition walls 155 are exposed through the resin partition walls 155.

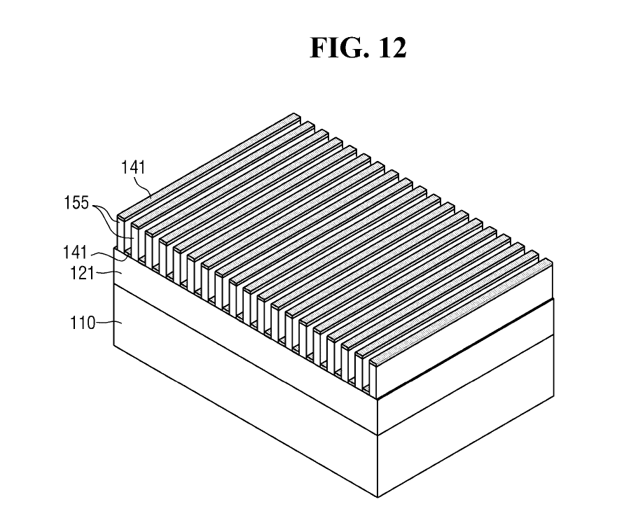

FIG. 12 schematically illustrates a process of forming the metal oxide layer 141 on the resin partition walls 155, and the some portions of the metal layer 121 exposed between the resin partition walls 155.

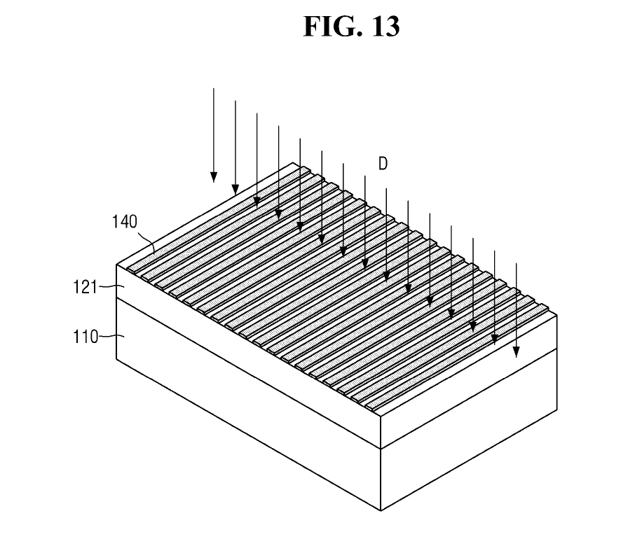

FIGS. 12 and 13 schematically illustrate a process of stripping the resin partition walls 155 and then patterning the metal layer 121 by using the metal oxide partition walls 140 disposed on the metal layer 121 spaced apart from one another as a mask.

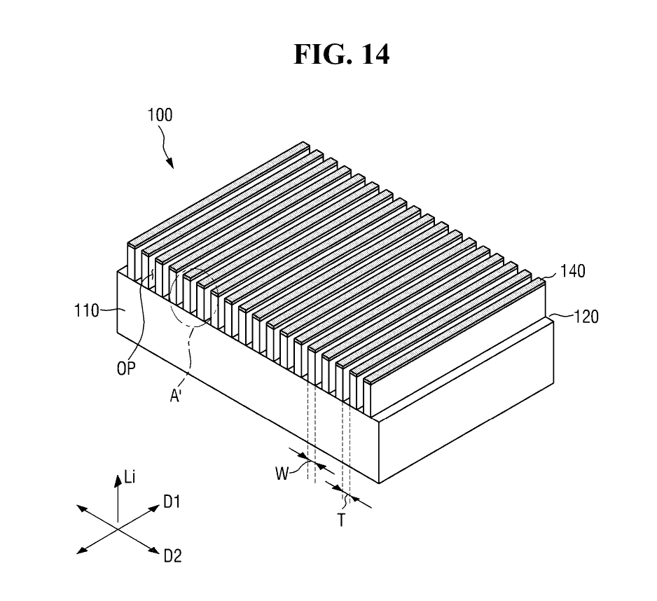

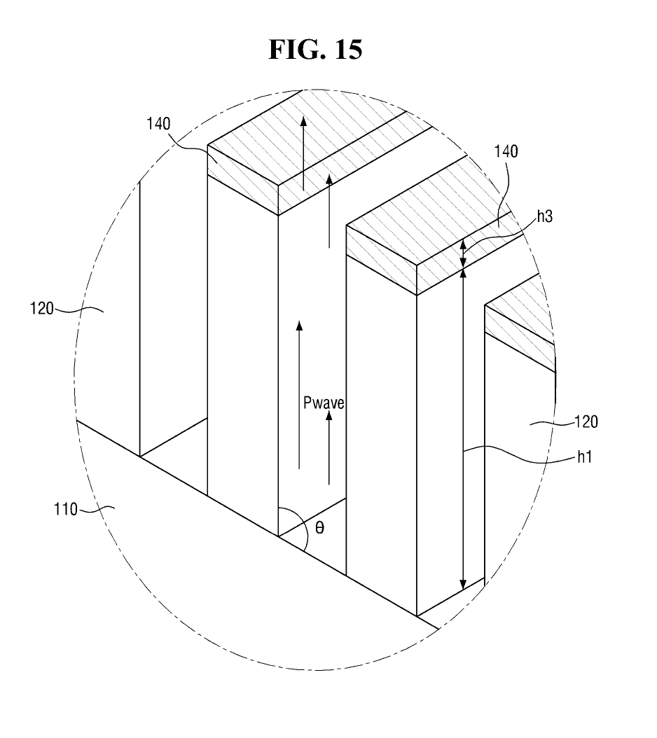

FIG. 14 schematically illustrates an exemplary embodiment of a wire grid polarizer plate 100 as a resulting product of the process shown in FIG. 13.

According to an exemplary embodiment of the disclosure, all of the processes of each of the methods are carried out continuously in a single sputter chamber, so that processing efficiency and productivity of the wire grid polarizer plate 100 may be improved.

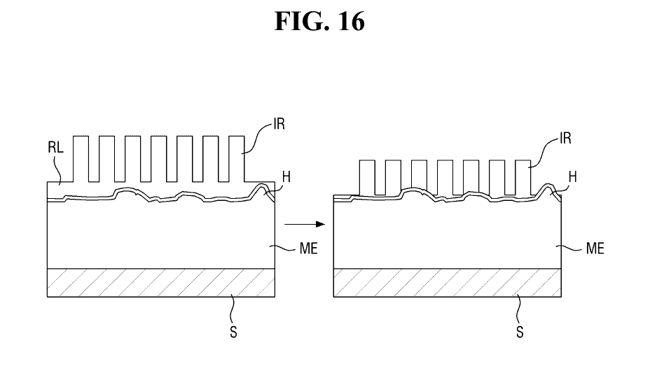

Hereinafter, improved characteristics of an exemplary embodiment of the wire grid polarizer plate 100 and an exemplary embodiment of the method of manufacturing the wire grid polarizer plate 100 compared to a conventional wire grid polarizer plate and a conventional method of manufacturing the wire grid polarizer plate will be described in greater detail with reference to FIGS. 16 to 27.

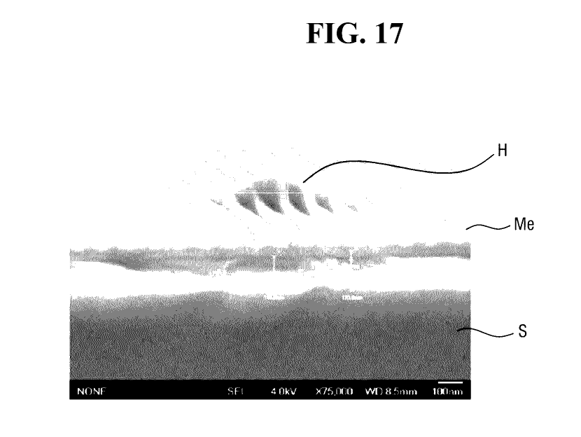

FIG. 16 is a view schematically showing existing conventional method of manufacturing a wire grid polarizer plate. FIG. 17 is an image showing a pattern defect on the wire grid polarizer plate caused by hill lock.

Referring to FIG. 16, according to a conventional method of manufacturing a wire grid polarizer plate, a metal layer Me was deposited on a transparent substrate S, a silicon oxide film was formed on the metal layer Me, the silicon oxide (SiOₓ) film was patterned by using a nano imprint mold (not shown), and residual silicon oxide film RL was stripped, thereby forming silicon oxide partition walls IR on the metal layer Me. Subsequently, the metal layer Me was patterned by using the silicon oxide partition walls IR as a mask, thereby manufacturing a wire grid polarizer plate.

Referring back to FIGS. 6 and 14, the conventional wire grid polarizer plate may include a transparent substrate 110, metal partition walls 120 disposed on the transparent substrate 110 and metal oxide partition walls 140 disposed on the metal partition walls 120, where the metal oxide partition walls 140 is made of silicon oxide.

The silicon oxide film is formed on the metal layer Me by the chemical vapor deposition (“CVD”) method, which is a high-temperature deposition process, such that hillock H may be formed on the metal layer Me. The hillock H results in uneven surface of the metal layer Me. Accordingly, when a nano imprint method is carried out with a nano imprint mold which comes in direct contact with the silicon oxide film, the uneven surface of the metal layer Me causes pattern defects in the nano imprint process.

Referring to FIG. 17, the hillock H formed on the metal layer Me during the process of forming the silicon oxide is not removed during the process of forming the wire grid pattern of the metal layer Me, and thus the hillock H remains in the wire grid pattern, thereby casing pattern defects.

In such a conventional method, to form the silicon oxide film on the metal layer Me, the transparent substrate S, on which the metal layer Me is formed, is transferred from a sputter chamber to a CVD chamber. As a result, processing efficiency is lowered.

In another conventional method, a capping layer may be formed on the metal layer such as a molybdenum (Mo) layer or a titanium (Ti) layer and then a silicon oxide film may be formed on the capping layer, to prevent the hillock on the metal layer formed during a CVD process. However, in such a conventional method, a process of deposing the capping layer on the metal layer is additionally performed, and thus processing efficiency is lowered.

Table 1 below shows experimental results of surface roughness of the wire grid polarizer plate according to Comparative Example 1. The wire grid polarizer plate according to Comparative Example 1 was manufactured by patterning an aluminum layer formed on a transparent substrate using silicon oxide partition walls as a mask. Referring to FIGS. 6 and 14, the wire grid polarizer plate according to Comparative Example 1 includes a transparent substrate 110, metal partition walls 120 disposed on the transparent substrate 110 and metal oxide partition walls 140 disposed on the metal partition walls 120, where the metal oxide partition walls 140 is made of silicon oxide.

TABLE 1

| | | | Surface | Surface |
|---|---|---|---|---|
| Partition | Measurement | Measure | Roughness | Roughness |
| Walls | Radius (μm) | Location | (RMS)(nm) | (Rp-v)(nm) |
| Al + SiO₂ | 3 | 1 | 6.26 | 189.7 |
| | 3 | 2 | 6.99 | 164.1 |
| | 3 | 3 | 6.4 | 128.8 |

| | | |
|---|---|---|
| Average | 6.55 | 160.87 |

* RMS stands for Root Mean Square
* Rp-v denotes difference between peak in cross section Rp and valley in cross section Rv.

Table 2 below shows experimental results of surface roughness of a wire grid polarizer plate according to Comparative Example 2. The wire grid polarizer plate according to Comparative Example 2 was manufactured by patterning a molybdenum layer formed on an aluminum layer using silicon oxide partition walls as a mask and then patterning the aluminum layer formed on a transparent substrate using the patterned molybdenum layer as a mask. Referring to FIGS. 6 and 14, the wire grid polarizer plate according to Comparative Example 2 includes a transparent substrate 110, metal partition walls 120 disposed on the transparent substrate 110, a capping layer (not shown) disposed on the metal partition walls 120, and metal oxide partition walls 140 disposed on the capping layer (not shown), where the capping layer is made of molybdenum and the metal oxide partition walls 140 is made of silicon oxide.

TABLE 2

| | | | Surface | Surface |
|---|---|---|---|---|
| Partition | Measurement | Measure | Roughness | Roughness |
| Walls | Radius (μm) | Location | (RMS)(nm) | (Rp-v)(nm) |
| Al + Mo + | 3 | 1 | 4.81 | 77.69 |
| SiO₂ | 3 | 2 | 4.69 | 98.27 |
| | 3 | 3 | 4.61 | 62.07 |

| | | |
|---|---|---|
| Average | 4.70 | 79.34 |

* RMS stands for Root Mean Square
* Rp-v denotes difference between peak in cross section Rp and valley in cross section Rv.

Table 3 below shows experimental results of surface roughness of an exemplary embodiment of a wire grid polarizer plate according to the invention. Such an embodiment of the wire grid polarizer plate was manufactured by patterning an aluminum layer formed on a transparent substrate using aluminum oxide partition walls as a mask, according to the method shown in FIGS. 1 to 6. Referring to FIG. 6, such an embodiment of the wire grid polarizer plate includes a transparent substrate 110, metal partition walls 120 disposed on the transparent substrate 110 and metal oxide partition walls 140 disposed on the metal partition walls 120, where the metal partition walls 120 is made of aluminum and the metal oxide partition walls 140 is made of aluminum oxide.

TABLE 3

| | | | Surface | Surface |
|---|---|---|---|---|
| Partition | Measurement | Measure | Roughness | Roughness |
| Walls | Radius (μm) | Location | (RMS)(nm) | (Rp-v)(nm) |
| Al + AlOₓ | 3 | 1 | 2.838 | 27.171 |
| | 3 | 2 | 2.646 | 25.533 |
| | 3 | 3 | 2.609 | 23.125 |

| | | |
|---|---|---|
| Average | 2.70 | 25.28 |

* RMS stands for Root Mean Square
* Rp-v denotes difference between peak in cross section Rp and valley in cross section Rv.

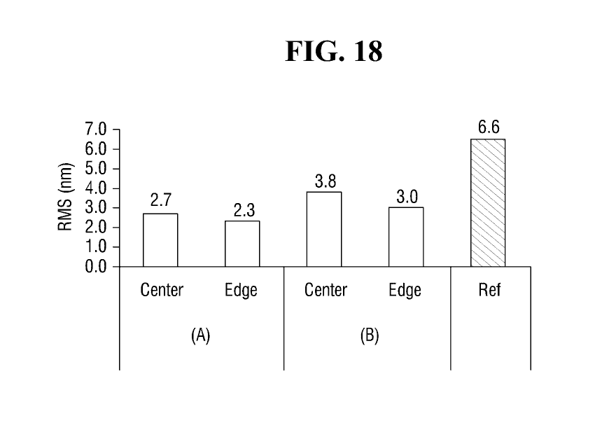

FIG. 18 is a graph showing results obtained by comparing and analyzing the RMS of the surface roughness of an exemplary embodiment of the wire grid polarizer plate according to the invention with that of the wire grid polarizer plate according to Comparative Example 1. FIG. 19 is a graph showing results obtained by comparing and analyzing the Rp-v of the surface roughness of an exemplary embodiment of the wire grid polarizer plate according to the invention with that of the wire grid polarizer plate according to Comparative Example 1.

FIGS. 18 and 19 shows a case where an exemplary embodiment of the wire grid polarizer plate (A) has aluminum partition walls having a thickness of about 2,000 Å0 and aluminum oxide partition walls having a thickness of about 300 Å, an alternative exemplary embodiment of the wire grid polarizer plate (B) according to the invention has aluminum partition walls having a thickness of about 1,500 Å and aluminum oxide partition walls having a thickness of about 300 Å, and a conventional wire grid polarizer plate (Ref) according to Comparative Example 1 has aluminum partition walls having a thickness of about 2,000 Å and silicon oxide (SiO₂) partition walls having a thickness of about 300 Å.

Referring to FIG. 18, in the exemplary embodiment of the wire grid polarizer plate (A), the average of RMS of surface roughness in the center was about 2.7 nm, and the average of RMS of surface roughness at the edge was 2.3 nm. In the exemplary embodiment of the wire grid polarizer plate (B), the average of RMS of surface roughness in the center was 3.8 nm, and the average of RMS of surface roughness at the edge was 3.0 nm. In the conventional wire grid polarizer plate (Ref) according to Comparative Example 1, the average of RMS of surface roughness was 6.6 nm.

Referring to FIG. 19, in the exemplary embodiment of the wire grid polarizer plate (A), the average of Rp-v of surface roughness in the center was 25.29 nm, and the average of Rp-v of surface roughness at the edge was 26.93 nm. In the exemplary embodiment of the wire grid polarizer plate (B), the Rp-v of surface roughness in the center was 36.48 nm, and the average of Rp-v of surface roughness at the edge was 25.69 nm. In the conventional wire grid polarizer plate (Ref) according to Comparative Example 1, the average of Rp-v of surface roughness was 160.87 nm.

As shown in Tables 1 to 3 and FIGS. 18 and 19, surface unevenness has been improved in an exemplary embodiment of the wire grid polarizer plates, compared to that of a conventional wire grid polarizer plate according to Comparative Examples. Referring to FIGS. 16 and 17, in the exemplary embodiment of the wire grid polarizer plate (A), the average of RMS of surface roughness has been reduced by approximately 61%, and the average of Rp-v of surface roughness has been reduced by approximately 82% .

In summary, surface unevenness of an exemplary embodiment of the wire grid polarizer plates is substantially improved compared to that of a conventional wire grid polarizer plate. In such an embodiment of the invention, by forming the aluminum oxide (AlOₓ) film by the sputtering method, instead of silicon oxide (SiOₓ) film typically formed using a high-temperature deposition process, such that aluminum hillock is effective prevented from being formed.

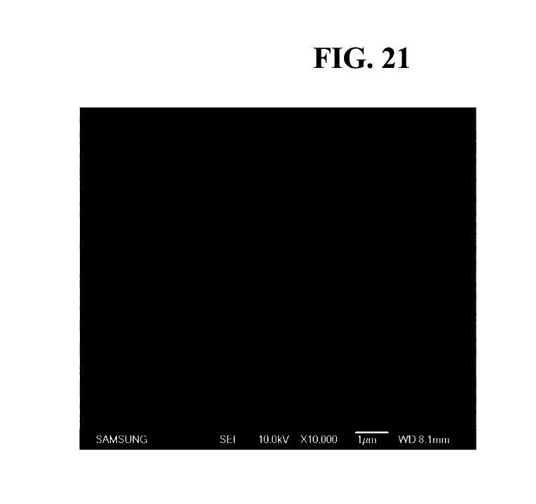

FIG. 20 is an image showing the surface of the wire grid polarizer plate according to Comparative Example 1. FIG. 21 is an image showing the surface of the wire grid polarizer plate according to an exemplary embodiment of the invention.

As shown in FIGS. 20 and 21, hillock was generated on the surface of the wire grid polarizer plate according to Comparative Example 1, but hillock was not generated in the wire grid polarizer plate according to the exemplary embodiment of the disclosure.

In an exemplary embodiment of the method of manufacturing a wire grid polarizer plate according to the invention, no additional capping layer is formed, thereby improving processing efficiency and productivity. In such an embodiment of the method of manufacturing a wire grid polarizer plate, the aluminum oxide (AlOₓ) film is formed, instead of a silicon oxide (SiOₓ) film, and thus, a transparent substrate on which a metal is formed is not transferred from a sputter chamber to a CVD chamber. As a result, in such an embodiment, processing efficiency and productivity may be improved.

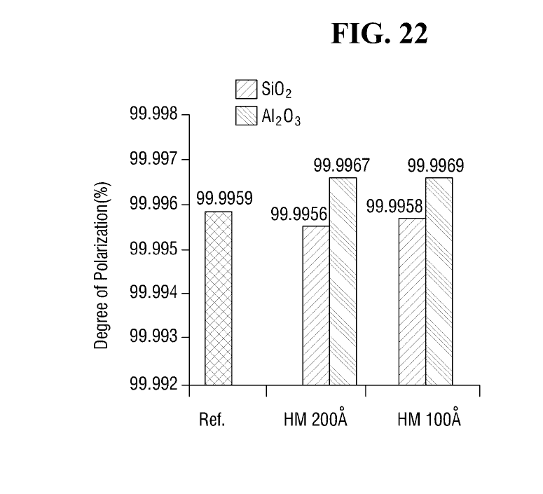

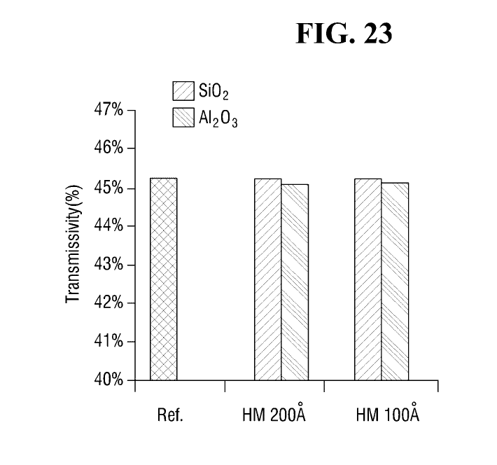

FIG. 22 is a graph for comparing degree of polarization of an exemplary embodiment of the wire grid polarizer plate with that of the wire grid polarizer plate according to Comparative Example 1. FIG. 23 is a graph for comparing transmissivity of an exemplary embodiment of the wire grid polarizer plate with that of the wire grid polarizer plate according to Comparative Example 1. In FIGS. 22 and 23, a control group Ref is a polarizing film.

As shown in FIGS. 22 and 23, an exemplary embodiment of the wire grid polarizer plate exhibits a higher degree of polarization and substantially equal transmissivity, compared to the control group Ref and Comparative Example 1. In FIG. 22, an exemplary embodiment of the wire grid polarizer plate exhibited the degree of polarization of 99.9967% when the thickness of the mask HM was 200 Å, and the degree of polarization of 99.9969% when the thickness of the mask HM was 100 Å. The control group exhibited the degree of polarization of 99.9959%, and the wire grid polarizer plate according to Comparative Example 1 exhibited the degree of polarization of 99.9956% when the thickness of the mask HM was 200 Å, and the degree of polarization of 99.9958% when the thickness of the mask HM was 100 Å. In FIG. 22, an exemplary embodiment of the wire grid polarizer plate exhibited the transmissivity of 45.24% when the thickness of the mask HM was 200 Å, and the transmissivity of 45.26% when the thickness of the mask HM was 100 Å. The control group exhibited the transmissivity of 45.43%, and the wire grid polarizer plate according to Comparative Example 1 exhibited the transmissivity of 45.38% when the thickness of the mask HM was 200 Å, and the transmissivity of 45.37% when the thickness of the mask HM was 100 Å.

FIG. 24 is a graph showing relationship between the thickness of aluminum oxide partition walls (Å) and residual film ratio (%) after the aluminum oxide (AlOₓ) layer has been patterned using resin partition walls as a mask.

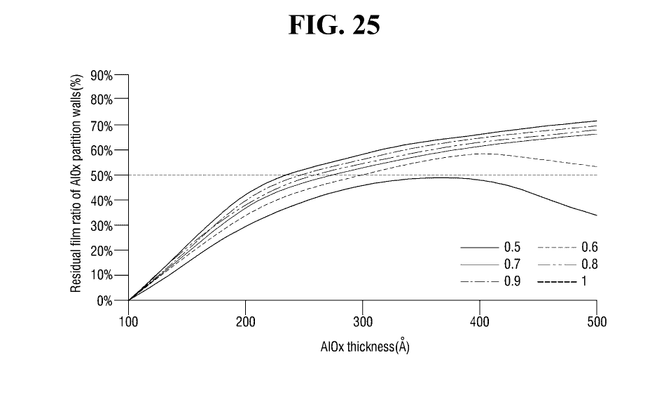

FIG. 25 is a graph showing relationship between the thickness of aluminum oxide partition walls (Å) and residual film ratio of aluminum oxide partition walls (%) after the aluminum layer has been patterned using aluminum oxide (AlOₓ) partition walls as a mask.

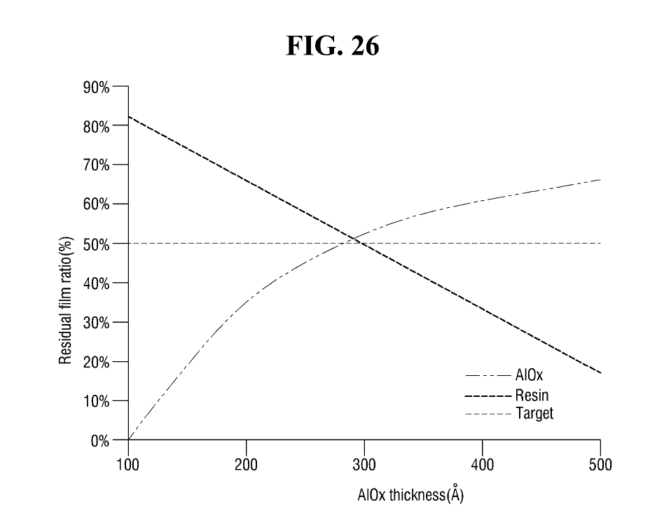

FIG. 26 is a graph showing the relationship among the residual film ratio (%) of resin partition walls, residual film ratio (%) of aluminum oxide partition walls and the thickness (Å) of aluminum oxide partition walls, when the etch selectivity between the resin partition walls and the aluminum oxide partition walls is about 1:0.8.

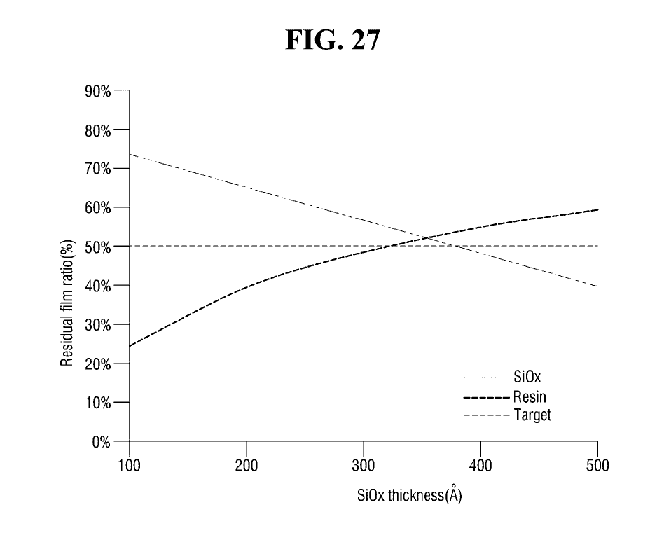

FIG. 27 is a graph showing the relationship among the residual film ratio (%) of resin partition walls, residual film ratio (%) of silicon oxide partition walls and the thickness (Å) of silicon oxide partition walls, when the etch selectivity between the resin partition walls and the silicon oxide (SiOₓ) partition walls is about 1:1.5.

As shown in FIGS. 24 to 27, when the etch selectivity between the resin partition walls and the aluminum oxide partition walls is about 1:0.8, i.e., when the thickness of the aluminum oxide partition walls is about 300 Å or more, by replacing silicon oxide partition walls with aluminum oxide partition walls as a mask, the residual film ratio of the resin partition walls and the residual film ratio of the aluminum oxide partition walls may be substantially equal to that of the silicon oxide partition walls.

While the invention has been particularly shown and described with reference to exemplary embodiments thereof, it will be understood by those of ordinary skill in the art that various changes in implementation and detail may be made therein without departing from the spirit and scope of the following claims. The exemplary embodiments should be considered in a descriptive sense only and not for purposes of limitation.

What is claimed is:

1. A wire grid polarizer plate comprising:
a transparent substrate;
metal partition walls disposed on the transparent substrate and spaced apart from one another, wherein the metal partition walls comprises at least one metal selected from aluminum (Al), titan (Ti), molybdenum (Mo), chrome (Cr), silver (Ag), copper (Cu), nickel (Ni) and cobalt (Co); and
metal oxide partition walls disposed on the metal partition walls, wherein the metal oxide partition walls comprises an oxide of the at least one metal,
wherein an average of surface roughness is about 4 nanometers or less when a thickness of the metal oxide partition walls is equal to about 300 angstrom.

2. The wire grid polarizer plate of claim 1, wherein an average of a difference −v between a peak in cross section of the metal oxide partition walls and a valley in cross section thereof is equal to or less than about 50 nanometers.

3. The wire grid polarizer plate of claim 1, wherein a degree of polarization is equal to or greater than about 99.9960%.

4. The wire grid polarizer plate of claim 1, wherein a Mohs hardness of the metal oxide partition walls is greater than a Mohs hardness of the metal partition walls.

5. The wire grid polarizer plate of claim 1, wherein the metal oxide partition walls is electrically conductive.

6. The wire grid polarizer plate of claim 1, wherein an angle formed by the transparent substrate and the metal partition walls is in a range from about 88° to about 90°.

7. A method of manufacturing a wire grid polarizer plate, the method comprising:
performing continuous sputtering depositions comprising:
injecting an inert gas into a sputter chamber to deposit a metal layer on a transparent substrate by sputtering; and
injecting the inert gas along with an oxygen gas into the sputter chamber to deposit a metal oxide layer on the metal layer by sputtering, wherein the metal layer comprises at least one metal selected from aluminum (Al), titan (Ti), molybdenum (Mo), chrome (Cr), silver (Ag), copper (Cu), nickel (Ni) and cobalt (Co), and the metal oxide layer comprises an oxide of the at least one metal;
providing resin partition walls on the metal oxide layer;
patterning the metal oxide layer using the resin partition walls as a mask to form metal oxide partition walls on the metal layer; and
patterning the metal layer using the metal oxide partition walls as a mask to form the metal partition walls on the transparent substrate.

8. The method of claim 7, wherein the performing the continuous sputtering depositions, the providing resin partition walls, the patterning the metal oxide layer and the patterning the metal layer are carried out in the sputter chamber.

9. The method of claim 7, wherein an etch selectivity between the resin partition walls and the metal oxide partition walls is in a range from about 1:0.8 to about 1:1 when a thickness of the metal oxide partition walls is in a range from about 300 Å to about 400 angstrom.

10. The method of claim 7, wherein a flow rate of the oxygen gas is about 50 standard cubic centimeters per minute or less.

11. A method of manufacturing a wire grid polarizer plate, the method comprising:
injecting an inert gas into a sputter chamber to deposit a metal layer on a transparent substrate by sputtering, wherein the metal layer comprises at least one metal selected from aluminum (Al), titan (Ti), molybdenum (Mo), chrome (Cr), silver (Ag), copper (Cu), nickel (Ni) and cobalt (Co);
providing resin partition walls on the metal layer;
injecting the inert gas with an oxygen gas into the sputter chamber to deposit a metal oxide layer on the resin partition walls and the metal layer by sputtering, wherein the metal oxide layer comprises an oxide of the at least one metal;
stripping the resin partition walls to form metal oxide partition walls on the metal layer, wherein the metal oxide partition walls is made of the oxide of the metal; and
patterning the metal layer using the metal oxide partition walls as a mask to form the metal partition walls on the transparent substrate.

12. The method of claim 11, wherein the providing resin partition walls on the metal layer, the stripping the resin partition walls and the patterning the metal layer are carried out in the sputter chamber.

13. The method of claim 11, wherein an etch selectivity between the resin partitioning walls and the metal oxide partitioning walls is in a range from about 1:0.8 to about 1:1 when a thickness of the metal oxide partitioning walls is in a range from about 300 angstrom to about 400 angstrom.

14. The method of claim 11, wherein a flow rate of the oxygen gas is about 50 standard cubic centimeters per minute or less.
